(19) United States
(12) Patent Application Publication
(10) Pub. No.: US 2017/0285430 A1
(43) Pub. Date: Oct. 5, 2017

(54) Array Substrate and Manufacturing Method Thereof, Display Panel and Display Device

(71) Applicants: BOE Technology Group Co., Ltd., Beijing (CN); Hefei BOE Optoelectronics Technology Co., Ltd., Hefei (CN)

(72) Inventors: Ling Hu, Beijing (CN); Xiangzhen Wang, Beijing (CN); Guohua Xu, Beijing (CN)

(73) Assignees: BOE Technology Group Co., Ltd., Beijing (CN); Hefei BOE Optoelectronics Technology Co., Ltd., Hefei (CN)

(21) Appl. No.: 15/508,319

(22) PCT Filed: Mar. 24, 2016
(86) PCT No.: PCT/CN2016/077193

§ 371 Date: Mar. 2, 2017

(30) Foreign Application Priority Data
Sep. 11, 2015 (CN) 201510580303.X

(51) Int. Cl. G02F 1/1362; G02F 1/1343; G02F 1/1368

(52) U.S. Cl. CPC G02F 1/136286; G02F 1/1368; G02F 1/134309; G02F 1/13439; G02F 2201/123; G02F 2001/13629; G02F 2201/121; G02F 2001/136295; G02F 2201/503; H01L 27/1244

(57) ABSTRACT

An array substrate, a manufacturing method thereof, a display panel and a display device are disclosed to solve the technical problem that defects are caused to signal line wiring in a periphery area of the array substrate due to pressure applied to a sealant. The array substrate comprises a display area and a periphery area which is provided with a signal line wiring, wherein the periphery area is provided with a protection layer which at least partially covers the signal line wiring.

### TECHNICAL FIELD

The present invention relates to a display technology field, and more particularly, to an array substrate, a manufacturing method thereof, a display panel, and a display device.

### BACKGROUND

Liquid crystal displays (LCDs) have advantages of small volume, light weight, low energy consumption, low radiation and the like, and are widely used in various electronic devices. LCDs typically comprise an array substrate, a color filter substrate and a liquid crystal layer disposed between the array substrate and the color filter substrate. Liquid crystal molecules in the liquid crystal layer are deflected by an electric field generated between electrodes disposed on the array substrate and/or the color filter substrate, so as to achieve display. According to various arrangement of the electrodes configured to generate an electric field, the LCDs can be classified into a Twisted Nematic (TN) LCD and an Advanced Super Dimension Switch (ADS) LCD.

An array substrate for the TN LCD comprises a display area and a periphery area, wherein the display area is provided with a pixel unit and a thin film transistor configured to control the pixel unit, the periphery area is provided with various wiring, which are configured to apply signals to the thin film transistor.

FIG. 1 shows an illustrative structural view of a TN LCD of prior arts. As shown in FIG. 1, a sealant 8 is disposed between an array substrate and a color filter substrate and corresponds to a periphery area, wherein the sealant 8 comprises a gold ball 81, which is configured to transfer common electrode signals on the array substrate to a common electrode disposed on the color filter substrate.

In the array substrate shown in FIG. 1, a common line wiring 2 and a gate line wiring 21, which are disposed on the same level as a gate electrode, are located in a portion of the first glass substrate 1 corresponding to the periphery area. A gate insulating layer 3 is disposed on the gate electrode, a data line wiring 4 which is on the same level as source/drain electrode is disposed on the gate insulating layer 3, a passivation layer 5 is disposed on the source/drain electrodes and the data line wiring 4, a pixel electrode 6 and a interconnection layer 61 which is on the same level as the pixel electrode 6 are disposed on the passivation layer 5, wherein the interconnection layer 61 is connected to the common line wiring 2 through a second via formed in the passivation layer 5 and a first via formed in the gate insulating layer 3. Thus, the common electrode signals are transferred from the common line wiring 2 to common electrode 9 disposed on the color filter substrate through the interconnection layer 61 and the gold ball 81.

In the color filter substrate as shown in FIG. 1, the second glass substrate 13 is provide with a color filter layer, which comprises pixels 12 disposed at intervals and black matrixes 11 disposed between the pixels 12. On the color filter layer, an insulation planarization layer 10 is provided. A common electrode 9 is disposed on the insulation planarization layer 10 and an orientation layer 7 is disposed on the common electrode 9.

With development of the liquid crystal display panel toward big size, high precision, high frequency, 3D and the like, it is required to develop an electrode material with low electric resistance for manufacturing gate lines, data lines, source/drain electrodes of a thin film transistor, pins and the like. As reduction in resistance of the electrode material will decrease resistance and capacitance delay (RC delay), dimensions of the gate line and the data line can be made with higher precision, and in turn, opening ration can be improved. At present, metal copper has become the first choice for electrode material due to its resistance of 2 μΩ·cm.

However, as the copper is soft, the copper has a lower resistance to pressure, and is prone to be oxidized when used for electrode material.

For a TN LCD with copper as electrode material, it has a low reliability due to high possibility of defects in wiring. Especially for main stream of narrow bazel, there are very small space provided in the periphery area, and it is required to dispose wiring on the gate electrode layer and the source/drain electrodes metal layer alternatively (each of the gate electrode layer and the source/drain electrodes metal layer is made of copper). As shown in FIG. 1, the gate line wiring 21, the data line wiring 4 and the common line wiring 2 are covered by the sealant 8, which comprises a gold ball 81. As the passivation layer 5 is fragile, and signal wiring (comprising gate line wiring 21, common line wiring 2 and/or data line wiring 4) are made of cop with low resistance to force, when the sealant 8 is pressed, the gold ball 81 will make the gate line wiring 21 and the common line wiring 2 short, or make the data line wiring 4 and the common line wiring 2 short, which seriously degrades the device.

For the ADS LCD with copper as material for electrodes, as shown in FIG. 2, a common electrode 9 is disposed on the array substrate rather than the color filter substrate, which is different from the configuration as shown in FIG. 1. Then, an electric field is generated between the common electrode 9 and a pixel electrode 6, each having a shape of slits, to control deflection of liquid crystal molecules, so as to achieve display.

At that time, the sealant 8 comprises a silicon ball 82 or a similar glass fiber configured to support. As the passivation layer 5 is very fragile, and as the signal wiring (comprising gate line wiring 21, common line wiring 2 and/or data line wiring 4) are made of copper with low resistance to pressure, when the sealant 8 is pressed, the silicon ball 82 will cause the passivation layer 5 and the signal wiring disposed in an area corresponding to the sealant 8 broke, which seriously degrades the product.

So, for current LCDs, even though such a defect can be mitigated or eliminated by thickening the passivation layer 5, a storage capacitance will be decreased due to increase in thickness of the passivation layer 5 according to the storage capacitance equation Cst=ε S/d, thereby increasing a leakage current and deteriorating display effect. And at the same time, cost for coating such a passivation layer and time for etching a via in the passivation layer will be increased.

### SUMMARY

In order to mitigate or solve the technical problems mentioned above, according to one aspect of the invention, an array substrate is provided, comprising a display area and a periphery area, the periphery area is provided with a signal line wiring, wherein the periphery area is provided with a protection layer which at least partially covers the signal line wiring.

Optionally, the protection layer completely covers the signal line wiring.

Optionally, the protection layer is made of metal or metal oxide.

Optionally, the metal oxide is Indium-Tin-Oxide or Indium Zinc Oxide.

Optionally, a gate metal layer, a gate insulating layer, a source/drain metal layer, a passivation layer and the protection layer are disposed in the periphery area of the array substrate.

Optionally, a gate metal layer, a gate insulating layer, an active layer, a source/drain metal layer, a passivation layer and a pixel electrode are disposed in the periphery area, and the protection layer and the pixel electrode are disposed on the same level and insulated from each other.

Optionally, the signal line wiring is distributed in the source/drain metal layer and/or the gate metal layer.

Optionally, the signal line wiring comprises a common line wiring and a gate line wiring disposed in the gate metal layer and a data line wiring disposed in the source/drain metal layer.

Optionally, the protection layer is electrically connected to the common line wiring through a second via formed in the passivation layer and a first via formed in the gate insulating layer.

Optionally, the display area of the array substrate is provided with a common electrode and a pixel electrode which are disposed insulated from each other, the protection layer and the common electrode or the pixel electrode are disposed on the same level and insulated from each other.

Optionally, the signal line wiring is distributed in the source/drain metal layer and/or the gate metal layer.

Optionally, the signal line wiring comprises a common line wiring and a gate line wiring disposed in the gate metal layer and a data line wiring disposed in the source/drain metal layer.

Optionally, the display area of the array substrate is provided with a gate metal layer, a gate insulating layer, an active layer, a soured/drain metal layer, an insulation layer, and a passivation layer disposed between the common electrode and the pixel electrode.

According to another aspect of the invention, a method for manufacturing the array substrate mentioned above is provided, comprising:

forming a thin film transistor on the base substrate; and

forming a pixel electrode and/or a common electrode on the base substrate on which the thin film transistor is formed and a protection layer through a patterning process.

Optionally, the protection layer and the pixel electrode or the common electrode are formed in one patterning process.

Optionally, the method comprising:

forming a gate metal layer on the base substrate, forming a pattern of a gate electrode in the display area of the array substrate and a pattern of a gate line wiring and a common line wiring which are disposed on the same level as the gate electrode in the periphery area of the array substrate through a patterning process;

forming a gate insulating layer and forming a pattern of the gate insulating layer through a patterning process, the pattern of the gate insulating layer comprising a first via formed in a portion of the gate insulating layer in the periphery area of the array substrate;

forming a semiconductor layer, and forming a pattern of an active layer through a patterning process;

forming a source/drain metal layer, and forming a pattern of source/drain electrodes in the display area of the array substrate and a pattern of the data line wiring and the common line wiring which are disposed on the same level as the gate electrode in the periphery area of the array substrate through a patterning process;

forming a passivation layer, and forming a second via in a portion of the passivation layer in the periphery area of the array substrate, the second via corresponding to the first via; and

forming a second conductive layer on the passivation layer, and forming a pixel electrode in the display area of the array substrate and a protection layer in the periphery area of the array substrate through one patterning process, wherein the protection layer is connected to the common line wiring through the first via and the second via.

Optionally, the method comprising:

forming a gate metal layer on the base substrate, forming a pattern of a gate electrode in the display area of the array substrate and a pattern of a gate line wiring and a common line wiring which are disposed on the same level as the gate electrode in the periphery area of the array substrate through a patterning process;

forming a gate insulating layer and forming a pattern of the gate insulating layer through a patterning process;

forming a semiconductor layer, and forming a pattern of an active layer through a patterning process;

forming a source/drain metal layer, and forming a pattern of source/drain electrodes in the display area of the array substrate and a pattern of the data line wiring which are disposed on the same level as the gate electrode in the periphery area of the array substrate through a patterning process;

forming an insulating layer;

forming a first conductive layer on the insulating layer and forming a common electrode or a pixel electrode on through a patterning process;

forming a passivation layer on the common electrode or the pixel electrode; and

forming a second conductive layer on the passivation layer, and forming a corresponding pixel electrode or a corresponding common electrode in the display area of the array substrate and a protection layer in the periphery area of the array substrate through one patterning process.

According to yet another aspect of the invention, a display panel is provided, comprising the array substrate mentioned above.

According to still another aspect of the invention, a display device is provided, comprising the display panel mentioned above.

In the array substrate, the manufacturing method thereof, the display panel, and the display device according to the present invention, a protection layer is disposed in a portion of the periphery area in contact with the sealant, the passivation layer is prevented from being pierced by a gold ball, a silicon ball or glass fiber, which will cause the signal line wiring short or broken, if there is a gold ball or a silicon ball in the sealant 8.

### BRIEF DESCRIPTION OF THE DRAWINGS

FIG. 1 is an illustrative structural view of a TN type display device of prior arts;

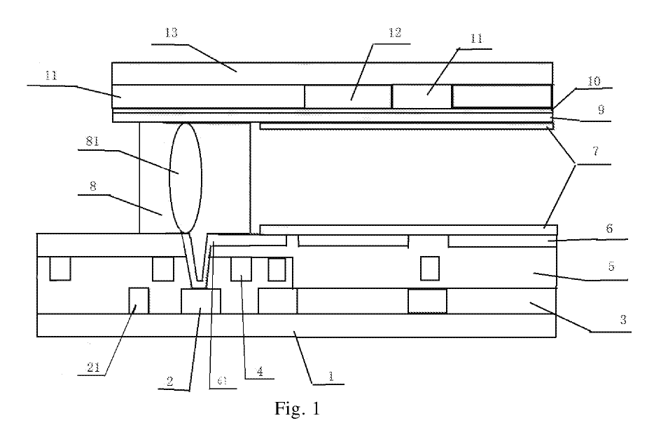

FIG. 2 is illustrative structural view of an ADS type display device of prior arts;

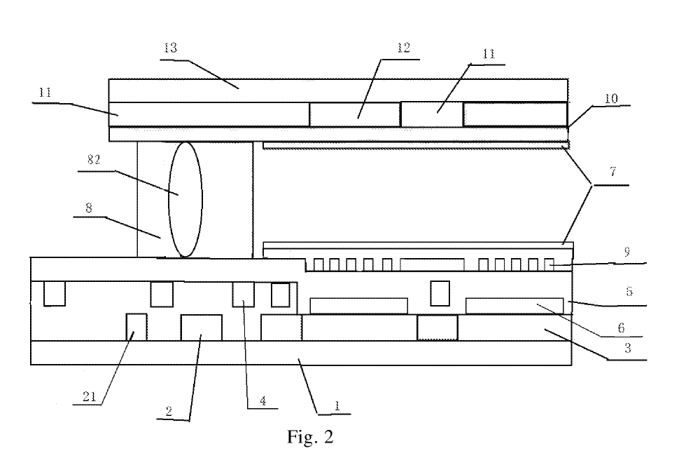

FIG. 3 is an illustrative structural view of a TN type display device according to the first or third embodiment of the invention; and

FIG. 4 is an illustrative structural view of an ADS type display device according to the second or fourth embodiment of the invention.

### DETAILED DESCRIPTION

In order to make one of ordinary skills in the art better understand the technical solution of the present invention, the invention will be described in detail with reference to the accompanying drawings and in connection with specific embodiments. It should be noted that, the accompanying drawings and the specific embodiments are intended to describe the present invention and are a part of the embodiments of the present invention, and cannot be construed as a limit to the present invention.

### The First Embodiment

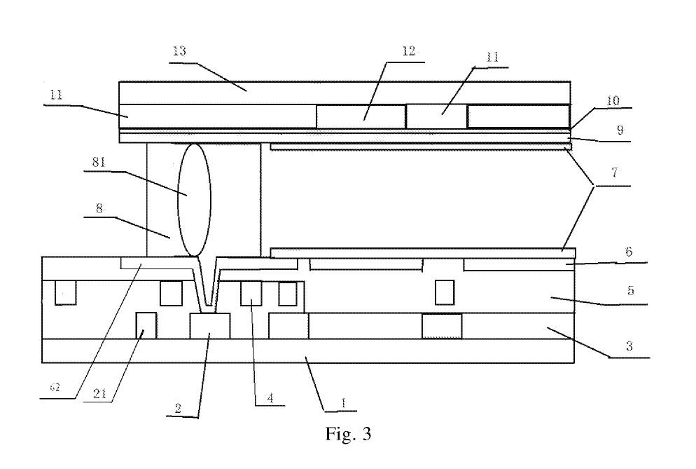

FIG. 3 illustrates an illustrative structural view of a TN type display device according to the first embodiment of the present invention. As shown in FIG. 3, an array substrate comprises a display area and a periphery area, which is provided with signal line wiring and further provided with a protection layer 62, the protection layer 62 at least partially covers the signal line wiring. In order to protect the signal line wiring to the greatest degree and prevent the signal line wiring from being short, the protection layer 62 can completely cover the signal line wiring.

In the array substrate according to this embodiment, as the protection layer 62 is provided in the periphery area, the protection layer 62 can prevent gold balls 81 in the sealant 8 from adversely affecting the signal line wiring of the array substrate after being pressed. That is to say, the gold balls 81 are prevented from piercing a passivation layer 5, which will make the signal line wiring short.

Optionally, the protection layer 62 is made of metal or metal oxide because the metal or the metal oxide has a great rigidity.

Additionally, as common electrode signals is required to be transferred to the common electrode 9 on the color filter substrate through the protection layer 62 in the TN type display device, the protection layer 62 is required to be conductive. Optionally, the protection layer 62 is made of metal or conductive metal oxide. Particularly, the metal oxide can comprise Indium-Tin-Oxide (ITO) or Indium Zinc Oxide (IZO).

It should be noted that, the protection layer 62 can be independently prepared through one patterning process. But, as illustrated in FIG. 3, if the protection layer 62 and the pixel electrode 6 are disposed on the same level, they can be formed of ITO or IZO through one patterning process, thereby saving process steps and reduce the cost.

For the TN type display device, the array substrate can be provided with a gate metal layer, a gate insulating layer 3, a source/drain metal layer, a passivation layer 5 and a protection layer 62 in the periphery area. It should be appreciated that, except the protection layer 62, the functional layers mentioned above each can be disposed in a manner according to the prior arts. It should be further appreciated that, functional layers disposed in the periphery area and corresponding functional layers disposed in the display area can be formed at the same time, remaining the functional layers mentioned above during patterning. The display area can further comprise other functional layers, such as an active layer and etc..

As a specific embodiment, as illustrate in FIG. 3, a passivation layer 5, a source/drain metal layer (that is, a layer in which the source/drain electrodes are disposed, and in which the data line wiring 4 can also be disposed), a gate insulating layer 3, a gate metal layer (the layer in which the gate electrode is disposed, and in which the common line wiring 2 and the gate line wiring 21 can also be disposed) are disposed in sequence in the periphery area of the array substrate in the direction from the protection layer 62 to the glass substrate 1. The protection layer 62 and the pixel electrode 6 in the display area are disposed on the same level and are insulated from each other.

It should be appreciated that, the signal line wiring can be disposed in the respective metal layers according to actual requirements and it is not restricted herein. For example, the signal line wiring can be distributed in the source/drain metal layer and/or in the gate metal layer. In the array substrate as illustrate in FIG. 3, the signal line wiring comprises a common line wiring 2 and a gate line wiring 21 disposed in the gate metal layer and a data line wiring 4 disposed in the source/drain metal layer.

It should be appreciated that, the present invention is applicable to a structure of top gate even though the embodiment is described by taking a structure of bottom gate as an example, the invention is not limited thereto.

Optionally, the protection layer 62 is electrically connected to the common line wiring 2 through a second via formed in the passivation layer 5 and a first via formed in the gate insulating layer 3. Thus, signals on the common line wiring 2 can be transferred to the common electrode 9 disposed on the color filter substrate through the protection layer 62. Thereby, when the gold balls 81 in the sealant 8 is in contact with the protection layer 62, signals for controlling the common electrode 9 is transferred from the common line wiring 2 to the protection layer 62 and then to the common electrode 9 disposed on the color filter substrate through the gold balls 81 in contact with the protection layer 62, so as to control deflection of liquid crystal molecules to achieve display.

As illustrated in FIG. 3, as the protection layer 62 and the pixel electrode 6 are disposed on the same level and insulated from each other (a portion of the protection layer 62 adjacent to the display area is separated from the pixel electrode 6), signals on the common electrode 9 and signals on the pixel electrode 6 will not interfere with each other.

It should be appreciated that, a gate metal layer, a gate insulating layer 3, an active layer (not shown), a source/drain metal layer, a passivation layer 5 and a pixel electrode 6 can be disposed in the display area of the array substrate.

A source electrode and a drain electrode are formed in the source/drain metal layer and insulated from each other, the source electrode is configured to receive signals from a data line, and the drain electrode is configured to be connected to the pixel electrode 6. A gate electrode is formed in the gate metal layer, and is configured to receive scanning signals. The active layer is controlled to be conductive by use of the scanning signals, so that signals on the data line are controlled to be transferred to the pixel electrode 6. Thus, an electrical field is generated between the pixel electrode 6 and the common electrode 9 to control the liquid crystal, thereby controlling deflection of the liquid crystal molecules.

The structure of a thin film transistor and the operation principle thereof are well known to one of ordinary skills in the art, and will not be elaborated herein.

### The Second Embodiment

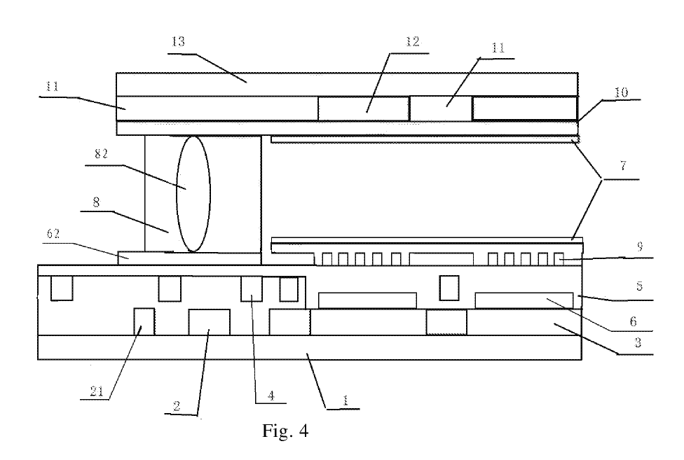

FIG. 4 illustrates an illustrative structural view of a TN type display device according to the second embodiment of the present invention. An array substrate according to the second embodiment comprises a display area and a periphery area, which is provided with signal line wiring and further provided with a protection layer 62, the protection layer 62 at least partially covers the signal line wiring. In order to protect the signal line wiring to the greatest degree and prevent the signal line wiring from being short, the protection layer 62 can completely cover the signal line wiring.

In the array substrate according to this embodiment, as the protection layer 62 is provided in the periphery area, the protection layer 62 can prevent gold balls 82 in the sealant 8 and/or glass fiber from adversely affecting the signal line wiring of the array substrate after being pressed. That is to say, supports such as the gold balls 82 and/or glass fiber are prevented from piercing a passivation layer 5, which will make the signal line wiring short.

Optionally, the protection layer 62 is made of metal or metal oxide because the metal or the metal oxide has a great rigidity. Thus, a better protection is provided.

Optionally, the metal oxide can comprise Indium-Tin-Oxide (ITO) or Indium Zinc Oxide (IZO). It should be appreciated that, the protection layer 62 can be independently prepared through one patterning process. But, as illustrated in FIG. 4, when the protection layer 62 and the common electrode 9 (or, the pixel electrode 6 in different configurations) are disposed on the same level, they can be formed of ITO or IZO through one patterning process, thereby saving process steps and reduce the cost.

More particularly, for the ADS type display device, the array substrate can be provided with a gate metal layer (disposed on the same level with the common line wiring 2 and the gate line wiring 21), a gate insulating layer 3, a source/drain metal layer (disposed on the same level with the data line wiring 4), a passivation layer 5 and a protection layer 62 (disposed in the same level with the pixel electrode 6 or the common electrode 9) in the periphery area. It should be appreciated that, except the protection layer 62, the functional layers mentioned above each can be disposed in a manner according to the prior arts.

It should be appreciated that, functional layers disposed in the periphery area and corresponding functional layers disposed in the display area can be formed at the same time, remaining the functional layers mentioned above during patterning. The display area can further comprise other functional layers, such as an active layer and etc..

As a specific implementation manner, as illustrate in FIG. 4, a passivation layer 5, a source/drain metal layer (on the same level with the data line wiring 4), a gate insulating layer 3, a gate metal layer (on the same level with the common line wiring 2 and the gate line wiring 21) are disposed in sequence in the periphery area of the array substrate in the direction from the protection layer 62 to the base substrate 1. The protection layer 62 and the common electrode 9 in the display area are disposed on the same level and are insulated from each other. Optionally, the protection layer 62 and the pixel electrode 6 in the display area can also be disposed on the same level and are insulated from each other. It is not restricted herein, as long as the protection layer 62 and one of the common electrode 9 and the pixel electrode 6 in the display area which is disposed farther away from the base substrate (for example, the glass substrate 1) are disposed on the same level.

It should be appreciated that, the signal line wiring can be disposed in the respective metal layers according to actual requirements and it is not restricted herein. For example, the signal line wiring can be distributed in the source/drain metal layer and/or in the gate metal layer. In the array substrate as illustrate in FIG. 4, the signal line wiring comprises a common line wiring 2 and a gate line wiring 21 disposed in the gate metal layer and a data line wiring 4 disposed in the source/drain metal layer.

It should be appreciated that, the present invention is applicable to a structure of top gate even though the embodiment is described by taking a structure of bottom gate as an example, the invention is not limited thereto.

Optionally, the common electrode 9 and the pixel electrode 6 are disposed in the display area of the array substrate and are insulated from each other, and the protection layer 62 and the common electrode 9 or the pixel electrode 6 are disposed on the same level, as long as the protection layer 62 and one of the common electrode 9 and the pixel electrode 6 that is disposed farther away from the base substrate of the array substrate. Thus, the protection layer 62 and one of the common electrode 9 and the pixel electrode 6 that is disposed farther away from the glass of the base substrate can be formed through one patterning process, thereby saving processing steps and reducing the cost.

It should be appreciated that, a gate metal layer, the gate insulating layer 3, an active layer (not shown), the source/drain metal layer, an insulating layer, and the passivation layer 5 disposed between the common electrode 9 and the pixel electrode 6 can be disposed in the display area of the array substrate.

A source electrode and a drain electrode are formed in the source/drain metal layer and separated from each other, the source electrode is configured to receive signals from a data line, and the drain electrode is configured to be connected to the pixel electrode 6. A gate electrode is formed in the gate metal layer, and is configured to receive scanning signals. The active layer is controlled to be conductive by use of the scanning signals, so that signals on the data line are controlled to be transferred to the pixel electrode 6. Thus, an electrical field is generated between the pixel electrode 6 and the common electrode 9 to control the liquid crystal, thereby controlling deflection of the liquid crystal molecules.

The structure of a thin film transistor and the operation principle thereof are well known to one of ordinary skills in the art, and will not be elaborated herein.

### The Third Embodiment

This embodiment provides a manufacturing method for an array substrate, comprising the following steps:

forming a thin film transistor on a base substrate; and

forming a pixel electrode 6 and a protection layer 62 on the base substrate on which the thin film transistor is formed, wherein the protection layer 62 and the pixel electrode 6 can be formed through one patterning process, thereby saving processing steps and reducing manufacturing cost.

Optionally, the manufacturing method comprising the following steps:

Forming a gate metal layer on the base substrate, and forming a pattern of a gate electrode in a display area of the array substrate and a pattern of gate line wiring 21 and common line wiring 2 which are disposed on the same level with the gate electrode in a periphery area of the array substrate through a patterning process;

Forming a gate insulating layer 3, and forming a pattern of the gate insulating layer 3 through a patterning process, the pattern of the gate insulating layer 3 comprising a via formed in a portion of the gate insulating layer 3 in the periphery area of the array substrate;

Forming a semiconductor layer, and forming a pattern of an active layer through a patterning process;

Forming a source/drain metal layer, and forming a pattern of source/drain electrodes in the display area of the array substrate and a pattern of a data line wiring 4 which is disposed on the same level as the source/drain electrodes in the periphery area of the array substrate through a patterning process;

Forming a passivation layer 5 and forming a second via in a portion of the passivation layer 5 in the periphery area of the array substrate through a patterning process, the second via corresponding to the first via;

Forming a conductive layer on the passivation layer 5, and forming a pixel electrode 6 in the display area of the array substrate and a protection layer 62 in the periphery area of the array substrate through a patterning process, wherein the protection layer 62 is connected to the common line wiring 2 through the first via and the second via.

Particularly, the manufacturing method is described by taking manufacturing processes for the TN type array substrate as illustrated in FIG. 3 as an example.

Step 1, forming a gate electrode in the display area and a gate line wiring 21 and a common line wiring 2 in the periphery area.

In this step, a buffer film layer and a copper film layer are deposited on the glass substrate 1 by sputtering or thermal evaporation. The buffer film layer has a thickness about 100-1000 Å, and material for the buffer film can comprises one of Ta, Cr, Mo, W, or Nb, or an alloy thereof, or other transparent conductive film. The copper film layer has a thickness about 1000-5000 Å.

Then, a pattern of a gate electrode in the display area and other wiring in the periphery area disposed on the same level with the gate electrode, such as the gate line wiring 21 and the common line wiring 2, are obtained through coating photoresist, exposing, developing, wet etching and peeling off.

Step 2: on the glass substrate 1 on which step 1 is finished, forming a gate insulating layer 3, forming an active layer of a thin film transistor in the display area, and forming a first via in a portion of the gate insulating layer 3 in the periphery area.

In this step, the gate insulating layer 3, the semiconductor layer, and an ohmic contact layer are formed through plasma enhanced chemical vapor deposition (PECVD). Wherein the gate insulating layer 3 has a thickness of 1000-4000 Å, and material for the gate insulating layer 3 can be nitrides (e.g., SiNx) or nitrogen oxides (e.g., SiOxNy), or a composite of nitrides (e.g., SiNx) and nitrogen oxides (e.g., SiOxNy). The semiconductor can have a thickness of 1000-4000 Å, and the ohmic contact layer can have a thickness of 500-1000 Å.

The active layer of the thin film transistor in the display area and the first via in the gate insulating layer 3 in the periphery area are obtained through coating photoresist, exposing, developing, wet etching and peeling off. And the semiconductor layer and the ohmic contact layer in the periphery area are removed.

Step 3: on the glass substrate 1 on which step 2 is finished, forming a source electrode, a drain electrode in the display area and a signal line wiring (such as data line wiring 4 and the like) in the periphery area which are disposed on the same level as the source electrode and the drain electrode.

In this step, a buffer layer with a thickness of 100-1000 Å is deposited on the glass substrate 1 on which step 2 is finished through sputtering or thermal evaporation. Material for the buffer layer can be one of Ta, Cr, Mo, W, and Nb, or an alloy thereof, or any other transparent conductive layer. And then a copper layer with a thickness of 1000-5000 Å is deposited. Optionally, the source/drain metal layer can be formed of multilayered metal.

The source electrode and the drain electrode in the display area and the signal line wiring in the periphery area which is disposed on the same level as the source/drain electrodes are obtained through coating photoresist, exposing, developing, wet etching and peeling off.

Step 4, forming a passivation layer 5 on the glass substrate 1 on which step 3 is finished and forming a second via in the passivation layer 5.

In this step, a passivation layer with a thickness of 700-5000 Å is deposited through plasma enhanced chemical vapor deposition (PECVD), and a second via is formed in a portion of the passivation layer 5 in the periphery area through a patterning process. The second via is communicated with the first via in the gate insulating layer 3. Material for the passivation layer 5 can be oxides, nitrides, or nitrogen oxides.

Step 5, on the glass substrate 1 on which step 4 is finished, forming a pixel electrode 6 in the display area and a protection layer 62 in the periphery area, wherein the protection layer 62 at least partially covers the wiring in the periphery area. Optionally, the protection layer 62 completely covers the wiring in the periphery area (such as the common line wiring 2, the gate line wiring 21 and the data line wiring, and the like).

In this step, a transparent conductive layer with a thickness of 300-1000 Å through sputtering or thermal evaporation. Material for the transparent conductive layer can be ITO or IZO, and can be other metal or metal oxide. The pixel electrode 6 in the display area and the protection layer 62 in the periphery area can be formed through one patterning process. Thus, it is not required for the protection layer 62 to be formed independently through one patterning process, thereby saving one patterning process.

Manufacturing other essential functional layers for the array substrate are well known to one of ordinary skills in the art and will not be elaborated herein.

It should be noted that, the array substrate is manufactured through five exposing processes. Otherwise, the array substrate can be manufacturing through four exposing processes. That is:

In step 2, after depositing the gate insulating layer 3, the semiconductor layer, the ohmic contact layer, and a buffer layer and the copper layer are deposited in sequence through sputtering or thermal evaporation while an exposing process and an etching process are not performed. And then, an exposing process and a developing process are performed by use of a half-tone mask or a grey-tone mask, and patterns comprising a first via in the gate insulating layer 3, the active layer, the source electrode, the drain electrode, and signal line wiring (such as data line wiring) disposed on the same level as the source/drain electrodes are formed through several etchings. There is no change in other steps.

In the array substrate formed through the steps mentioned above and illustrated in FIG. 3, the protection layer 62 which is in contact with the sealant 8 is formed with the pixel electrode 6 through one patterning process, thereby saving one patterning process and reducing the cost.

### The Fourth Embodiment

This embodiment provides a manufacturing method for an array substrate, comprising the following steps:

forming a thin film transistor on a base substrate; and

forming a pixel electrode 6 and a protection layer 62 on the base substrate on which the thin film transistor is formed, wherein the protection layer 62 and the pixel electrode 6 or the common electrode 9 are formed through one patterning process, thereby saving processing steps and reducing manufacturing cost.

More particularly, the manufacturing method comprising the following steps:

forming a gate metal layer on the base substrate, and forming a pattern of a gate electrode in a display area of the array substrate and a pattern of gate line wiring 21 and common line wiring 2 which are disposed on the same level as the gate electrode in a periphery area of the array substrate through a patterning process;

forming a gate insulating layer 3, and forming a pattern of the gate insulating layer through a patterning process,

forming a semiconductor layer, and forming a pattern of an active layer through a patterning process;

forming a source/drain metal layer, and forming a pattern of source/drain electrodes in the display area of the array substrate and a pattern of a data line wiring 4, which is disposed on the same level with the source/drain electrodes, in the periphery area of the array substrate through a patterning process;

forming an insulation layer;

forming a first conductive layer, and forming a common electrode 9 or a pixel electrode 6 on the insulation layer through a patterning process;

forming a passivation layer 5 on the common electrode 9 or the pixel electrode 6;

forming a second conductive layer on the passivation layer 5, and forming a corresponding pixel electrode 6 or a corresponding common electrode 9 in the display area of the array substrate and a protection layer 62 in the periphery area of the array substrate through a patterning process, wherein the protection layer 62 at least partially covers the signal line wiring in the periphery area. Optionally, the protection layer completely covers the line wiring in the periphery area (such as the common line wiring 2, the gate line wiring 21, and data line wiring and the like).

The ADS type array substrate as illustrated in FIG. 4 can be formed through the manufacturing method mentioned above. The manufacturing method is similar to the manufacturing method for the TN type array substrate, will not be elaborated herein. The protection layer 62 can be formed with the common electrode 9 or the pixel electrode 6 through one patterning process, thereby saving one patterning process and reducing the cost. It should be noted that, positions of the common electrode 9 and the pixel electrode 6 can be interchanged, and it is not restricted in the present invention, as long as the protection layer 62 and one of the common electrode 9 and the pixel electrode 6 in the display area which is disposed farther away from the glass substrate 1 are disposed on the same level.

### The Fifth Embodiment

This embodiment provides a display panel, which can comprise the array substrate according to the first or second embodiment. A TN type display panel or an ADS type display panel can comprise the array substrate according to the first or second embodiment, and a color filter substrate which is cell-assembled with the array substrate. Optionally, a color filter layer can be integrated in the array substrate. Then, the display panel can comprise the array substrate and a counter substrate. Additionally, the display panel can be implemented in other manners that can be implemented currently, and it is not restricted herein.

### The Sixth Embodiment

This embodiment provides a display device, comprising the display panel according to the fifth embodiment. The display device can be any device with display function, such as a TV, a computer, a cell phone, a digital camera, an ATM, an e-billboard and the like.

It should be appreciated that, the embodiments mentioned above are merely exemplary embodiments which are intended to explain the principle of the invention, and the invention is not limited thereto. Without departing the spirit and the essence of the invention, one of ordinary skills in the art can made various variation and modification to the invention, which also fall within the protection scope of the invention.

1. An array substrate, comprising a display area and a periphery area which is provided with a signal line wiring, wherein the periphery area is provided with a protection layer which at least partially covers the signal line wiring.

2. The array substrate according to claim 1, wherein the protection layer completely covers the signal line wiring.

3. The array substrate according to claim 1, wherein the protection layer is made of metal or metal oxide.

4. The array substrate according to claim 3, wherein the metal oxide is Indium-Tin-Oxide or Indium Zinc Oxide.

5. The array substrate according to claim 1, wherein a gate metal layer, a gate insulating layer, a source/drain metal layer, a passivation layer and the protection layer are disposed in the periphery area of the array substrate.

6. The array substrate according to claim 5, wherein a gate metal layer, a gate insulating layer, an active layer, a source/drain metal layer, a passivation layer and a pixel electrode are disposed in the periphery area, and the protection layer and the pixel electrode are disposed on the same level and insulated from each other.

7. The array substrate according to claim 6, wherein the signal line wiring is distributed in the source/drain metal layer and/or the gate metal layer.

8. The array substrate according to claim 7, wherein the signal line wiring comprises a common line wiring and a gate line wiring disposed in the gate metal layer and a data line wiring disposed in the source/drain metal layer.

9. The array substrate according to claim 8, wherein the protection layer is electrically connected to the common line wiring through a second via formed in the passivation layer and a first via formed in the gate insulating layer.

10. The array substrate according to claim 5, wherein the display area of the array substrate is provided with a common electrode and a pixel electrode which are insulated from each other, the protection layer and the common electrode or the pixel electrode are disposed on the same level and insulated from each other.

11. The array substrate according to claim 10, wherein the signal line wiring is distributed in the source/drain metal layer and/or the gate metal layer.

12. The array substrate according to claim 11, wherein the signal line wiring comprises a common line wiring and a gate line wiring disposed in the gate metal layer and a data line wiring disposed in the source/drain metal layer.

13. The array substrate according to claim 10, wherein the display area of the array substrate is provided with a gate metal layer, a gate insulating layer, an active layer, a soured/drain metal layer, an insulation layer, and a passivation disposed between the common electrode and the pixel electrode.

14. A manufacturing method for the array substrate according to claim 1, comprising the following steps:
forming a thin film transistor on the base substrate; and
forming a pixel electrode and/or a common electrode through a patterning process in the display area of the base substrate on which the thin film transistor is formed, and forming a protection layer in the periphery area through a pattering process.

15. The manufacturing method according to claim 14, wherein the protection layer is formed with the pixel electrode or the common electrode through one patterning process.

16. The manufacturing method according to claim 15, comprising:
forming a gate metal layer on the base substrate, forming a pattern of a gate electrode in the display area of the array substrate and a pattern of a gate line wiring and a common line wiring which are disposed on the same level as the gate electrode in the periphery area of the array substrate through a patterning process;
forming a gate insulating layer and forming a pattern of the gate insulating layer through a patterning process, the pattern of the gate insulating layer comprising a first via formed in a portion of the gate insulating layer in the periphery area of the array substrate;
forming a semiconductor layer, and forming a pattern of an active layer through a patterning process;
forming a source/drain metal layer, and forming a pattern of source/drain electrodes in the display area of the array substrate and a pattern of the data line wiring which is disposed on the same level as the gate electrode in the periphery area of the array substrate through a patterning process;
forming a passivation layer, and forming a second via in a portion of the passivation layer in the periphery area of the array substrate, the second via communicating with the first via; and
forming a second conductive layer on the passivation layer, and forming a pixel electrode in the display area of the array substrate and a protection layer in the periphery area of the array substrate through one patterning process;
wherein the protection layer is connected to the common line wiring through the first via and the second via.

17. The manufacturing method according to claim 15, comprising:
forming a gate metal layer on the base substrate, forming a pattern of a gate electrode in the display area of the array substrate and a pattern of a gate line wiring and a common line wiring which are disposed on the same level as the gate electrode in the periphery area of the array substrate through a patterning process;
forming a gate insulating layer and forming a pattern of the gate insulating layer through a patterning process;
forming a semiconductor layer, and forming a pattern of an active layer through a patterning process;
forming a source/drain metal layer, and forming a pattern of source/drain electrodes in the display area of the array substrate and a pattern of the data line wiring which are disposed on the same level as the gate electrode in the periphery area of the array substrate through a patterning process;
forming an insulating layer;
forming a first conductive layer on the insulating layer and forming a common electrode or a pixel electrode on through a patterning process;
forming a passivation on the common electrode or the pixel electrode; and
forming a second conductive layer on the passivation layer, and forming a corresponding pixel electrode or a corresponding common electrode in the display area of the array substrate and a protection layer in the periphery area of the array substrate through one patterning process.

18. A display panel, comprising an array substrate according to claim 1.

19. A display device, comprising the display panel according to claim 18.

20. The array substrate according to claim 2, wherein a gate metal layer, a gate insulating layer, a source/drain metal layer, a passivation layer and the protection layer are disposed in the periphery area of the array substrate.
